(19) United States
(12) Patent Application Publication
(10) Pub. No.: US 2026/0009822 A1
(43) Pub. Date: Jan. 8, 2026

(54) PROBE CARD FOR LOOPBACK TEST, PROBE HEAD THEREOF, PROBE SYSTEM, TESTING METHOD AND TESTED DEVICE

(71) Applicant: MPI CORPORATION, CHU-PEI CITY (TW)

(72) Inventors: CHIN-TIEN YANG, CHU-PEI CITY (TW); CHIN-YI TSAI, CHU-PEI CITY (TW); HUI-PIN YANG, CHU-PEI CITY (TW)

(73) Assignee: MPI CORPORATION, CHU-PEI CITY (TW)

(21) Appl. No.: 19/250,709

(22) Filed: Jun. 26, 2025

Related U.S. Application Data
(60) Provisional application No. 63/667,764, filed on Jul. 4, 2024.

(30) Foreign Application Priority Data
May 8, 2025 (TW) 114117315

(51) Int. Cl. G01R 1/067; G01R 1/073; G01R 31/317

(52) U.S. Cl. CPC G01R 1/06772; G01R 1/07342; G01R 31/31716

(57) ABSTRACT

A probe head includes a probe seat, vertical probes, and coaxial probes. The vertical probes are slidably inserted in guiding holes of the probe seat, and have lower end portions for contacting electrically conductive contacts of a device under test. The coaxial probe includes a probe main body provided from the outside to the inside thereof coaxially with an outer conductor, a dielectric layer and an inner conductor in order, and a tip unit disposed at a lower end portion of the probe main body and including first and second tips electrically connected with the outer and inner conductors respectively for contacting electrically conductive contacts of the device under test. The coaxial probes include first and second loopback probes composing a loopback probe pair for being configured as a part of a loopback test path. As a result, the present invention meets the high-frequency loopback test requirements.

### BACKGROUND OF THE INVENTION

### 1. Field of the Invention

The present invention relates generally to probe cards and more particularly, to a probe card for a loopback test, a probe head thereof, and a probe system and a testing method using the probe card.

### 2. Description of the Related Art

Nowadays, high-speed networks (e.g. PAM4 448 Gbps) are widely used. When testing electronic devices used in data centers of high-speed networks or long-distance communications, probe cards that can meet high-frequency testing requirements are needed. For example, the corresponding frequency is 120 GHz, which belongs to the millimeter wave (mm Wave) range. However, there is currently no probe card in the industry that can perform such high-frequency loopback tests to electronic devices with area array bump layouts. As far as we know, probe cards that simply use vertical probes or membrane probes cannot meet the high-frequency loopback test requirements such as 120 GHz. Because high-frequency signals (e.g. 120 GHz) have extremely high requirements on the geometric shapes and impedance matching of transmission lines, the common designs of vertical probes and membrane probes cannot effectively control the reflection and loss of these high-frequency signals. Besides, in high-frequency tests, the signal transmission channels, such as leads, probes and test points, between the probe card and the device under test will be affected by the dielectric effect. The traditional designs of vertical probes and membrane probes cannot effectively handle the propagation characteristics of these high-frequency signals.

### SUMMARY OF THE INVENTION

The present invention has been accomplished in view of the above-noted circumstances. It is an objective of the present invention to provide a probe card for a loopback test and a probe head thereof, which can meet the high-frequency loopback test requirements, thereby applicable to test electronic devices for high-speed network applications.

To attain the above objective, the present invention provides a probe head of a probe card for a loopback test, which is adapted to test a device under test. The device under test includes a plurality of electrically conductive contacts, such as contact pads or bumps. The probe head includes a probe seat, a plurality of vertical probes, and a plurality of coaxial probes. The probe seat includes at least one die unit. The die unit includes a plurality of guiding holes. Each vertical probe includes an upper end portion, a lower end portion, and a main body extending into an elongated shape between the upper end portion and the lower end portion. The vertical probes are slidably inserted in the guiding holes of the probe seat. The lower end portions of the vertical probes are adapted to contact the electrically conductive contacts of the device under test. The plurality of coaxial probes are disposed in the probe seat. Each coaxial probe includes a probe main body and a tip unit. The probe main body includes a plurality of electrical conductors electrically insulated from each other. The tip unit is disposed at a lower end portion of the probe main body. The tip unit includes a first tip and a second tip. The first tip and the second tip are electrically connected with two aforementioned electrical conductors of the probe main body respectively. The first tip and the second tip are adapted to contact the electrically conductive contacts of the device under test. The plurality of coaxial probes include a first loopback probe and a second loopback probe. The first loopback probe and the second loopback probe compose a loopback probe pair. The loopback probe pair is adapted to be configured as a part of a loopback test path.

The coaxial probe mentioned in the present invention refers to a type of probe which can use a ground signal to protect a testing signal. The testing signal transmitting path thereof is provided on the periphery thereof with a ground signal transmitting path, so that the testing signal and the ground signal are transmitted in the coaxial probe closely to each other. That can achieve great high-frequency testing effect. Therefore, the coaxial probe in the present invention includes the plurality of electrical conductors, so that two electrical conductors located close to each other, i.e. those electrically connected with the first and second tips respectively, can be used to transmit the ground signal and the testing signal respectively to attain the coaxial probe effect. In other words, the coaxial probe mentioned in the present invention is unlimited to have components actually arranged coaxially, but includes any type of probe that can attain the above-described coaxial probe effect.

In the embodiments of the present invention, the plurality of electrical conductors of the probe main body of each coaxial probe include an outer conductor and an inner conductor. The probe main body further includes a dielectric layer. The outer conductor, the dielectric layer and the inner conductor are arranged coaxially from the outside to the inside of the probe main body in order. The first tip and the second tip of the tip unit are electrically connected with the outer conductor and the inner conductor respectively. Such coaxial probe is the type having components actually arranged coaxially. The inner conductor thereof is adapted to transmit the testing signal, and the outer conductor is adapted to transmit the ground signal, so that the testing signal is surrounded by the ground signal. That can attain even greater high-frequency testing effect.

Since even tiny contact misalignments during high-frequency tests can lead to measurement errors, the contact accuracy and contact stability are critical to the testing results. When the vertical probes and the coaxial probes are integrated in the same probe seat, the vertical probes offer greater design flexibility to the layout of the probe seat than other types of probes do. This means the vertical probes are convenient to coordinate with the coaxial probes, and that is especially suitable for testing the devices under test with fine pitch or complex layouts. This allows for more flexible adjustment of the relative positioning of the vertical probes and the coaxial probes within the probe seat. Accordingly, integrating the coaxial probes and the vertical probes in the same probe seat facilitates more stable arrangement of the coaxial probes and enables the both types of probes to make more stable and precise mechanical contact with the device under test. This reduces contact issues such as probe slippage or misalignment from the centers of the electrically conductive contacts of the device under test. Such design helps establish the loopback test path. As a result, the first loopback probe and the second loopback probe can be connected by a connecting structure to form the loopback test path, enabling the device under test to generate a loopback signal and enabling loopback to progress through the loopback test path. For example, the device under test sends the loopback signal to the first loopback probe, then the loopback signal is transmitted through the loopback test path and transmitted back to the device under test from the second loopback probe, thereby enabling the loopback test of the device under test. Besides, the probes used for the loopback test are the coaxial probes, such as the above-described coaxial probes with inner and outer conductors. The inner conductor can be used to transmit the loopback signal, while the outer conductor can transmit the ground signal. Therefore, the coaxial probes perform well in transmitting high-frequency signals, so that the probe head of the present invention can meet the high-frequency loopback test requirements, thereby applicable to test electronic devices for high-speed network applications. This design enables the vertical probes to be placed adjacent to the coaxial probes or even integrated with the coaxial probes to collectively present a regular alignment, effectively testing electronic devices with high-speed and high-density distribution of electrically conductive contacts.

Preferably, the probe main bodies of the plurality of coaxial probes are located outside the plurality of vertical probes.

As a result, the area where the vertical probes are distributed can be regarded as a central region, and the probe main bodies of the coaxial probes are disposed on the periphery of the central region. That is, the coaxial probes are arranged around the vertical probes. This not only provides high flexibility in probe arrangement, but also facilitates the adjustment of the probe pressure of the coaxial probes to make the probe pressure of the coaxial probes match the probe pressure of the vertical probes, which means the probe pressures are similar or identical.

Preferably, the guiding holes of the die unit each extend along a vertical axis. The probe main body of each coaxial probe includes an inclined section inclined relative to the vertical axis. On an imaginary plane parallel to the vertical axis, the vertical probe is straight, and there is an included angle between the vertical probe and the inclined section of the coaxial probe.

As a result, by the arrangement of the geometric positions of the coaxial probes, it is convenient to adjust the probe pressure of the coaxial probes to make the probe pressure of the coaxial probes match the probe pressure of the vertical probes.

More preferably, the included angle between the vertical probe and the inclined section of the coaxial probe on the imaginary plane is smaller than 90 degrees. Such coaxial probe is even more convenient for the adjustment of the probe pressure thereof, thereby facilitating the matching of the probe pressure of the coaxial probes with the probe pressure of the vertical probes.

Preferably, the plurality of coaxial probes include two first loopback probes and two second loopback probes. The two first loopback probes and the two second loopback probes compose two loopback probe pairs. The two loopback probe pairs are adapted to be configured as parts of two loopback test paths. The two loopback probe pairs are arranged to transmit a differential signal.

As a result, the probe head of the present invention can be provided with many coaxial probes, and the coaxial probes can be arranged as a plurality of loopback probe pairs, so as to form a plurality of loopback test paths. Each loopback test path can transmit a loopback signal, so two adjacent loopback test paths can be used to transmit the differential signal. That is, the two adjacent loopback test paths compose a differential pair. In this way, the signal transmission is less susceptible to noise interference, thereby ensuring the integrity and accuracy of the signal.

Alternatively, the loopback probe pair can be arranged to transmit a single-ended signal. In other words, the aforementioned loopback signal transmitted through the first loopback probe and the second loopback probe is unlimited in type thereof, which may be the differential signal or the single-ended signal. Even if the loopback test paths are not arranged as the differential pair, but arranged to transmit the single-ended signal individually, the coaxial probes can achieve the anti-interference effect to a certain extent, making the signal transmission stable.

Preferably, the at least one die unit includes an upper die unit and a lower die unit, and may optionally further include a middle die unit disposed between the upper die unit and the lower die unit. The probe seat includes an opening penetrating through the upper die unit and the lower die unit. In the condition with the middle die unit, the opening also penetrates through the middle die unit. The plurality of coaxial probes are accommodated in the opening.

As a result, even if the electrically conductive contacts which the first and second tips of the coaxial probe should contact are located below the central region of the probe head, which means the first and second tips of the coaxial probe should be located in the central region of the probe head, the probe main body of the coaxial probe can extend toward the periphery of the probe seat inclinedly in the opening of the probe seat, such that it is unnecessary to arrange the entire coaxial probe in the central region of the probe head, resulting in higher flexibility of the arrangement of the coaxial probes.

Preferably, the probe seat is H-shaped and includes a central region, and two openings located on two opposite sides of the central region respectively. The plurality of coaxial probes are accommodated in the two openings.

As a result, the first loopback probe and the second loopback probe can be disposed in the two openings respectively, which facilitates the connection of the first loopback probe with the second loopback probe by a connecting structure to form the loopback test path. Besides, the H-shaped probe seat has not only the central region and the two openings, but also two elongated outside regions parallel to each other, resulting in high structural strength of the probe seat and great connection of the probe seat with an interface board connected therewith, such as a space transformer.

Preferably, the probe seat includes a central region, and the plurality of coaxial probes are arranged on two opposite sides of the central region.

As a result, the first loopback probe and the second loopback probe can be disposed on the two opposite sides of the central region respectively, that facilitates the connection of the first loopback probe with the second loopback probe by a connecting structure to form the loopback test path.

More preferably, the plurality of vertical probes are arranged in the central region. The first tips and second tips of the plurality of coaxial probes are arranged on the two opposite sides of the central region.

As a result, when the test is performed to the device under test, the central region is located right above the electrically conductive contacts of the device under test. Arranging all the vertical probes in the central region facilitates the vertical probes contacting the electrically conductive contacts of the device under test. Arranging the first tips and second tips of the coaxial probes on the two opposite sides of the central region enables the first and second tips of the coaxial probes to contact the electrically conductive contacts of the device under test, and facilitates the probe main bodies of the coaxial probes extending toward the periphery of the probe seat, such that it is unnecessary to arrange the entire coaxial probe in the central region of the probe head, resulting in higher flexibility of the arrangement of the coaxial probes.

Preferably, the lower end portions of at least a part of the vertical probes and the first tips and second tips of at least a part of the coaxial probes are substantially arranged in a straight line.

As a result, for the device under test with the electrically conductive contacts arranged in an array, the electrically conductive contacts thereof are arranged in a plurality of straight lines. Arranging the lower end portions of the vertical probes and the first and second tips of the coaxial probes in a straight line facilitates their contact with the electrically conductive contacts arranged in a straight line, thereby ensuring that the vertical probes and the coaxial probes can be easily aligned with the electrically conductive contacts of the device under test accurately at the same time, so as to improve the testing accuracy. Furthermore, it enhances the manufacturing efficiency. The arrangement in a straight line helps simplifying the probe installation process, reducing time for positioning and adjusting the tips.

In an embodiment of the present invention, the first loopback probe and the second loopback probe are electrically connected with a loopback test circuit of a space transformer.

As a result, the first and second loopback probes and the loopback test circuit of the space transformer collectively form the loopback test path. Such loopback test path is relatively shorter and easy to arrange. Besides, the required properties of the loopback test path and the signal it transmits can be adjusted through the circuit of the space transformer. For example, in the condition that the loopback test path is used to transmit the differential signal, the phase difference of the differential signal can be more easily adjusted through the circuit of the space transformer.

More preferably, an upper end portion of the probe main body of the first loopback probe and an upper end portion of the probe main body of the second loopback probe are connected to the space transformer and thereby electrically connected with the loopback test circuit.

As a result, the upper end portions of the first and second loopback probes can be directly connected to the space transformer. For example, the upper end portions of the first and second loopback probes are fixed to the space transformer by welding. This allows the first and second loopback probes and the loopback test circuit of the space transformer to collectively form the loopback test path.

More preferably, the loopback test path is provided thereon with an electronic component having signal filtering ability. The electronic component is located on the loopback test circuit of the space transformer.

As a result, in the condition requiring an electronic component to filter the signal transmitted through the loopback test path, the electronic component can be disposed on the loopback test circuit of the space transformer. For example, the electronic component may be a filter capacitor. Specifically, it may be, for example, a silicon capacitor. It is used to filter out DC signals while allowing only AC signals to pass through the loopback test path (DC Blocking/AC Coupling). The loopback test circuit of the space transformer is convenient to be provided with the electronic component in a way that the electronic component is electrically connected with the electrical conductors of the first and second loopback probes for transmitting the loopback signal so as to exert its effect on the signal transmitted by the first and second loopback probes.

In other embodiments of the present invention, the first loopback probe and the second loopback probe are connected by a coaxial structure. The coaxial structure includes an outer conductor, a dielectric layer and an inner conductor, which are arranged coaxially from the outside to the inside of the coaxial structure in order. The outer conductor of the first loopback probe and the outer conductor of the second loopback probe are electrically connected with the outer conductor of the coaxial structure. The inner conductor of the first loopback probe and the inner conductor of the second loopback probe are electrically connected with the inner conductor of the coaxial structure.

As a result, the first and second loopback probes and the coaxial structure collectively form the loopback test path. The coaxial structure has the same configuration with the probe main bodies of the first and second loopback probes, thereby also having great high-frequency signal transmission performance, that is beneficial for the probe head to meet the high-frequency loopback test requirements. Besides, the coaxial structure and the probe main bodies of the first and second loopback probes can be even manufactured as a same element. That is, a same coaxially configured element is used to form the probe main bodies of the first and second loopback probes and the coaxial structure connected therebetween, such that the manufacture is relatively easier.

More preferably, the loopback test path is provided thereon with an electronic component having signal filtering ability. The electronic component is located in the coaxial structure and electrically connected with the inner conductor of the coaxial structure.

As a result, in the condition requiring an electronic component to filter the signal transmitted through the loopback test path, the electronic component can be disposed in the coaxial structure, especially the section of the coaxial structure exposed on the outside of the probe head. For example, the electronic component may be a filter capacitor. Specifically, it may be, for example, a silicon capacitor. In this way, it is convenient to dispose the electronic component in a way that the electronic component is electrically connected with the inner conductors of the first and second loopback probes so as to exert its effect on the signal transmitted by the first and second loopback probes.

Preferably, the vertical probes are adapted to transmit signals between the device under test and a tester. The coaxial probes only transmit signals to each other and transmit signals to and from the device under test.

As a result, the tester can provide a drive signal to the device under test through the vertical probe to drive the device under test to generate the loopback signal. The coaxial probes can receive the loopback signal and transmit the loopback signal to each other so that the loopback of the loopback signal progresses through the coaxial probes to return the loopback signal to the device under test.

Preferably, the ratio of the contact force of anyone of the first tip and the second tip to the contact force of the tip of the vertical probe is larger than 0.5 and smaller than 2.

As a result, the first and second tips of the coaxial probe match the tip of the vertical probe in contact force, which means the contact forces of the tips are similar or identical. Specifically speaking, among the contact force of anyone of the first and second tips of the coaxial probe and the contact force of the tip of the vertical probe, the larger one is smaller than the double of the smaller one, so the aforementioned ratio is larger than 0.5 and smaller than 2. This allows the coaxial probe and the vertical probe to generate similar or identical probe pressure to the electrically conductive contacts of the device under test.

Preferably, the ratio of the outer diameter of anyone of the first and second tips to the outer diameter of the tip of the vertical probe is larger than 0.5 and smaller than 2. As a result, the first and second tips of the coaxial probe match the tip of the vertical probe in wear rate, which means the wear rates of the tips are similar or identical. This feature is attained by providing the first and second tips of the coaxial probe and the tip of the vertical probe similar or identical outer diameters. Specifically speaking, among the outer diameter of anyone of the first and second tips of the coaxial probe and the outer diameter of the tip of the vertical probe, the larger one is smaller than the double of the smaller one, so the aforementioned ratio is larger than 0.5 and smaller than 2. This allows the tips to have similar or identical wear rates, thereby maintaining great probe planarity even after prolonged use, meaning that the terminal ends of the tips are approximately located on a same horizontal plane.

To attain the above objective, the present invention provides a probe card for a loopback test, which is adapted to be applied in a probe system for testing a device under test. The probe card includes an above-described probe head, a main circuit board for being electrically connected to a tester, and a space transformer. The main circuit board includes an upper surface and a lower surface. The space transformer is disposed between the probe head and the lower surface of the main circuit board so that the vertical probes of the probe head are electrically connected with the main circuit board through the space transformer.

As a result, the probe card of the present invention using the above-described probe head can meet the high-frequency loopback test requirements, thereby applicable to test electronic devices for high-speed network applications.

In an embodiment of the present invention, the probe main bodies of the first loopback probe and the second loopback probe of the probe head penetrate through the probe seat, the space transformer and the main circuit board.

As a result, it is convenient to dispose a connecting structure on the upper surface of the main circuit board to connect the first and second loopback probes by the connecting structure, so that the first and second loopback probes and the connecting structure collectively form the loopback test path.

Preferably, the plurality of electrical conductors of the probe main body of each coaxial probe include an outer conductor and an inner conductor. The probe main body further includes a dielectric layer. The outer conductor, the dielectric layer and the inner conductor are arranged coaxially from the outside to the inside of the probe main body in order. The first tip and the second tip of the tip unit are electrically connected with the outer conductor and the inner conductor respectively. The first loopback probe and the second loopback probe of the probe head are connected by a coaxial structure. The coaxial structure includes an outer conductor, a dielectric layer and an inner conductor, which are arranged coaxially from the outside to the inside of the coaxial structure in order. The outer conductor of the first loopback probe and the outer conductor of the second loopback probe are electrically connected with the outer conductor of the coaxial structure. The inner conductor of the first loopback probe and the inner conductor of the second loopback probe are electrically connected with the inner conductor of the coaxial structure. The coaxial structure is located on the upper surface of the main circuit board.

As a result, the first and second loopback probes and the coaxial structure collectively form the loopback test path. The coaxial structure has the same configuration with the probe main bodies of the first and second loopback probes, thereby also having great high-frequency signal transmission performance, which is beneficial for the probe head to meet the high-frequency loopback test requirements. Besides, the coaxial structure and the probe main bodies of the first and second loopback probes can be even manufactured as a same element. That is, a same coaxially configured element is used to form the probe main bodies of the first and second loopback probes and the coaxial structure connected therebetween, such that the manufacture is relatively easier.

In another embodiment of the present invention, the probe main bodies of the first loopback probe and the second loopback probe of the probe head penetrate through the probe seat and the space transformer.

As a result, a connecting structure can be disposed inside or outside the probe seat and/or the space transformer to connect the first and second loopback probes by the connecting structure, so that the first and second loopback probes and the connecting structure collectively form the loopback test path.

Preferably, the plurality of electrical conductors of the probe main body of each coaxial probe include an outer conductor and an inner conductor. The probe main body further includes a dielectric layer. The outer conductor, the dielectric layer and the inner conductor are arranged coaxially from the outside to the inside of the probe main body in order. The first tip and the second tip of the tip unit are electrically connected with the outer conductor and the inner conductor respectively. The first loopback probe and the second loopback probe of the probe head are connected by a coaxial structure. The coaxial structure includes an outer conductor, a dielectric layer and an inner conductor, which are arranged coaxially from the outside to the inside of the coaxial structure in order. The outer conductor of the first loopback probe and the outer conductor of the second loopback probe are electrically connected with the outer conductor of the coaxial structure. The inner conductor of the first loopback probe and the inner conductor of the second loopback probe are electrically connected with the inner conductor of the coaxial structure. The coaxial structure is located on the lower surface of the main circuit board.

As a result, the first and second loopback probes and the coaxial structure collectively form the loopback test path. The coaxial structure has the same configuration with the probe main bodies of the first and second loopback probes, thereby also having great high-frequency signal transmission performance, which is beneficial for the probe head to meet the high-frequency loopback test requirements. Besides, the coaxial structure and the probe main bodies of the first and second loopback probes can be even manufactured as a same element. That is, a same coaxially configured element is used to form the probe main bodies of the first and second loopback probes and the coaxial structure connected therebetween, such that the manufacture is relatively easier.

In an embodiment of the present invention, the coaxial structure is disposed along a periphery of the space transformer.

As a result, the coaxial structure can be arranged to extend on the periphery of the space transformer according to the positions of the first and second loopback probes. In this way, the coaxial structure is prevented from interference with the vertical probes and/or circuits of the space transformer, thereby relatively easier to be arranged.

In another embodiment of the present invention, the space transformer includes an upper surface facing toward the main circuit board, a lower surface facing toward the probe head, an accommodating recess recessed from the upper surface of the space transformer, and a circuit layer located between the accommodating recess and the lower surface of the space transformer. The coaxial structure is inserted in the accommodating recess and located between the lower surface of the main circuit board and the circuit layer.

As a result, the coaxial structure can extend through the accommodating recess of the space transformer to be connected between the first and second loopback probes. Such connection has a relatively shorter path, so it can save material and can reduce signal interference.

The present invention further provides a probe system for testing a device under test. The probe system includes a chuck for supporting the device under test, a tester, and an above-described probe card. The probe card is electrically connected with the tester for contacting the device under test to make the tester electrically connected with the device under test for performing an electrical property testing process.

As a result, the probe system of the present invention using the above-described probe card can meet the high-frequency loopback test requirements, thereby applicable to test electronic devices for high-speed network applications.

The present invention further provides a testing method for testing a device under test. The device under test includes a plurality of electrically conductive contacts. The testing method includes the steps of:
providing a probe card having an above-described probe head;
making the lower end portions of the vertical probes and the first tips and second tips of the coaxial probes of the probe card contact the electrically conductive contacts of the device under test respectively; and
providing a drive signal to the device under test through the vertical probe of the probe card to drive the device under test to generate a loopback signal of a given type, and making loopback of the loopback signal progress through the first loopback probe and the second loopback probe, so that the first loopback probe and the second loopback probe transmit the loopback signal between a receiving end and a sending end of the device under test.

As a result, the testing method of the present invention can be used to perform a loopback test to the device under test. The testing method using the above-described probe head can meet the high-frequency loopback test requirements, thereby applicable to test electronic devices for high-speed network applications.

Preferably, the probe head includes two loopback probe pairs, and the loopback signal of the aforementioned given type is a differential signal.

As a result, the testing method of the present invention uses two loopback test paths to transmit the differential signal, making the signal transmission less susceptible to noise interference, thereby ensuring the integrity and accuracy of the signal.

Alternatively, the loopback signal of the aforementioned given type can be a single-ended signal. In other words, in the testing method of the present invention, the loopback signal transmitted by the first and second loopback probes is unlimited in type thereof. It may be the differential signal, or may be the single-ended signal. Even if the loopback signal is the single-ended signal, the coaxial probes can achieve the anti-interference effect to a certain extent, making the signal transmission stable.

The present invention further provides a tested device. The tested device is a device which has been tested through an electrical property testing process, and the electrical property testing process is performed by using the above-described testing method.

As a result, the tested device has been tested by the probe head and the testing method having the above-described advantages and effects. The test results thereof have stable and great precision, which can ensure the tested device has good performance.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic view of a probe system according to a first preferred embodiment of the present invention;

FIG. 2 is a front view of a probe card according to the first preferred embodiment of the present invention;

FIG. 3 is a sectional view taken along the line 3-3 in FIG. 2;

FIG. 4 is a sectional view taken along the line 4-4 in FIG. 2;

FIG. 5 is a bottom view of a probe head and a space transformer of the probe card according to the first preferred embodiment of the present invention;

FIG. 6 is an assembled perspective view of the probe head and the space transformer of the probe card according to the first preferred embodiment of the present invention;

FIG. 7 is an enlarged view of the part A in FIG. 6;

FIG. 8 is a front view of a probe card according to a second preferred embodiment of the present invention;

FIG. 9 is a sectional view taken along the line 9-9 in FIG. 8;

FIG. 10 and FIG. 11 are assembled perspective views of the probe card according to the second preferred embodiment of the present invention;

FIG. 12 is an enlarged view of the part B in FIG. 11;

FIG. 13 is a front view of a probe card according to a third preferred embodiment of the present invention;

FIG. 14 is a sectional view taken along the line 14-14 in FIG. 13;

FIG. 15 is a bottom view of the probe card according to the third preferred embodiment of the present invention;

FIG. 16 is an assembled perspective view of the probe card according to the third preferred embodiment of the present invention;

FIG. 17 is a front view of a probe card according to a fourth preferred embodiment of the present invention;

FIG. 18 is a sectional view taken along the line 18-18 in FIG. 17;

FIG. 19 is an assembled perspective view of a probe head and a space transformer of the probe card according to the fourth preferred embodiment of the present invention; and

FIG. 20 is a flow chart of a testing method provided by the present invention.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

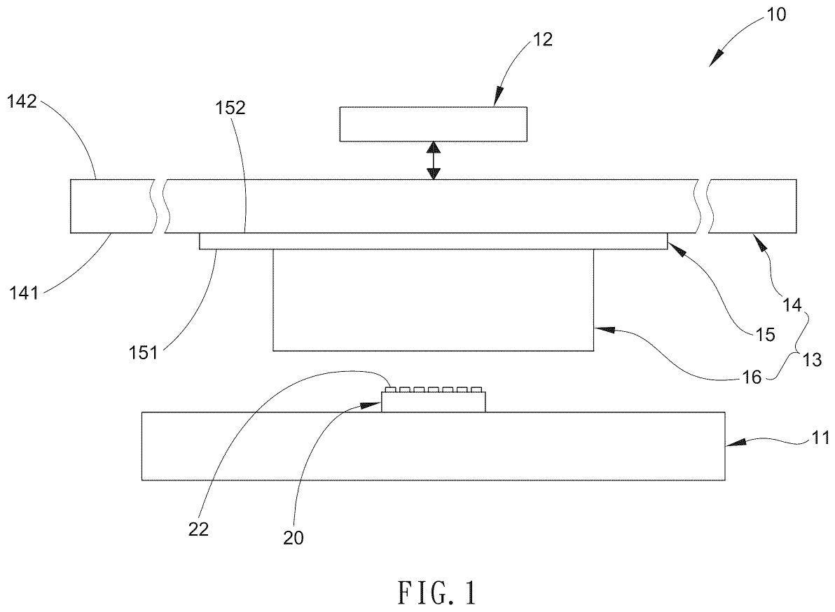

Referring to FIG. 1, a probe system 10 according to a first preferred embodiment of the present invention is adapted to test a device under test 20. For example, the device under test 20 may be, but unlimited to, an electronic device used in data centers of high-speed networks or long-distance communications. The device under test 20 includes a plurality of electrically conductive contacts 22. For example, the electrically conductive contacts 22 of the device under test 20 may be, but unlimited to, bumps or contact pads arranged in an array. The electrically conductive contacts 22 of the device under test 20 are actually tiny in size and huge in amount. For the simplification of the figures and the convenience of illustration, only a small amount of electrically conductive contacts 22 are schematically shown in FIG. 1, and the electrically conductive contacts 22 are drawn with relatively larger size.

The probe system 10 includes a chuck 11 for supporting the device under test 20, a tester 12, and a probe card 13. The probe card 13 includes a main circuit board 14, a space transformer 15, and a probe head 16 (also referred to as PH). The probe head 16 includes many contact probes for contacting the electrically conductive contacts 22 of the device under test 20 respectively, which will be specified hereinafter. For the simplification of the figures and the convenience of illustration, the contact probes are not shown in FIG. 1, and the probe head 16 is schematically represented by a rectangle in FIG. 1. The detailed structure of the probe head 16 is shown in other figures. The main circuit board 14 is adapted to be electrically connected with the tester 12. The space transformer 15 (also referred to as ‘ST’) is disposed between the probe head 16 and the lower surface 141 of the main circuit board 14 for the space transformation between the contact probes of the probe head 16 and the electrically conductive contacts (not shown) of the lower surface 141 of the main circuit board 14. That is, the intervals between the electrically conductive contacts (not shown) of the lower surface 151 of the space transformer 15 for being electrically connected with the contact probes are smaller than the intervals between the electrically conductive contacts (not shown) of the upper surface 152 of the space transformer 15 for being electrically connected with the main circuit board 14. As a result, when the contact probes of the probe card 13 contact the electrically conductive contacts 22 of the device under test 20, the tester 12 is electrically connected with the device under test 20 through the probe card 13, such that it can perform an electrical property testing process to test the electrical properties of the device under test 20.

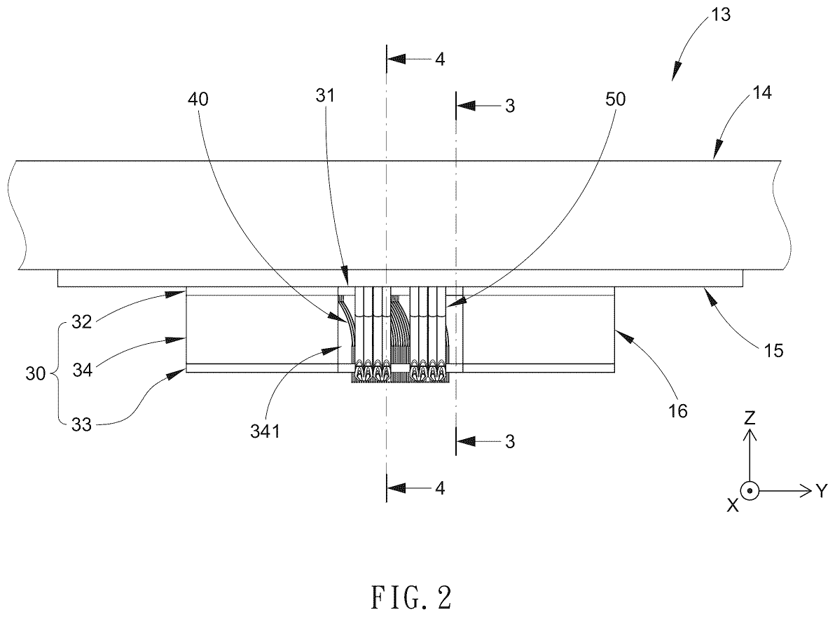

Referring to FIG. 2 to FIG. 7, the probe head 16 in this embodiment includes an H-shaped probe seat 30, and two kinds of contact probes are disposed in the probe seat 30, including vertical probes 40 and coaxial probes 50. The probe seat 30 includes a central region 31. Each vertical probe 40 is entirely inserted in the central region 31. Each coaxial probe 50 is mostly located outside two outer edges 311 and 312 of the central region 31.

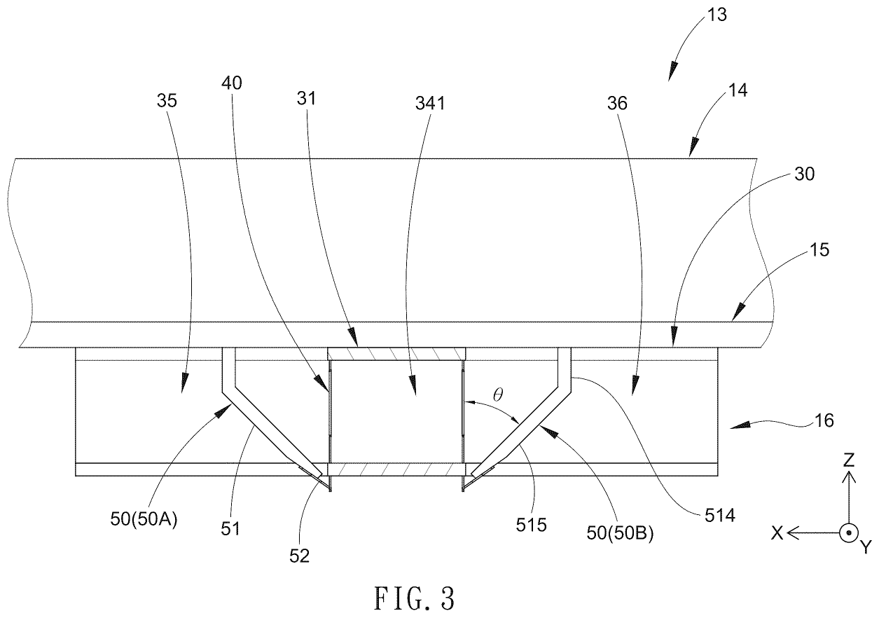

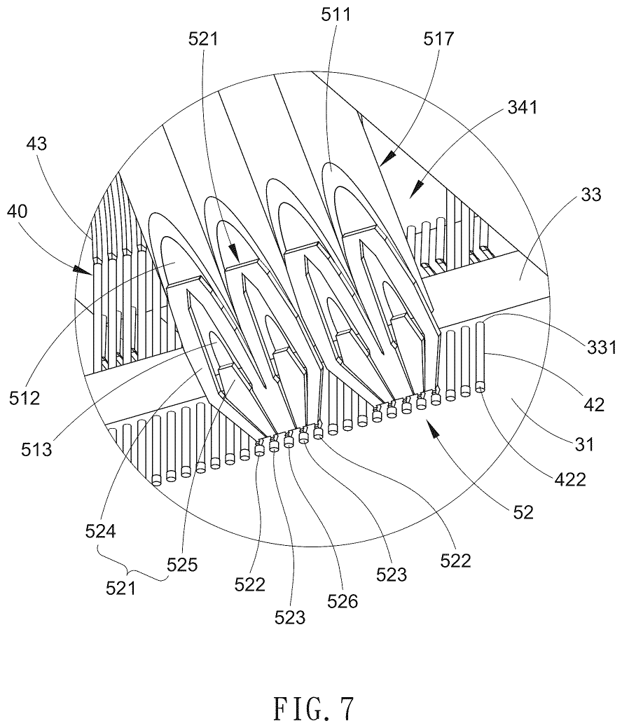

The probe seat 30 in this embodiment includes an upper die unit 32, a lower die unit 33, and a middle die unit 34 disposed between the upper die unit 32 and the lower die unit 33. However, the probe seat 30 may include only the upper and lower die units but no such middle die unit. Alternatively, the probe seat 30 can include at least one die unit. In this embodiment, each die unit includes only one die. However, each die unit may be composed of a plurality of dies piled on one another. It can be seen in FIG. 7 that the lower die unit 33 includes a plurality of guiding holes 331 for the vertical probes 40 to be inserted therein. The guiding holes 331 penetrate through the body of the lower die unit 33 along a vertical axis, i.e. Z-axis shown in FIG. 2 and FIG. 3. Similarly, the upper die unit 32 also includes a plurality of guiding holes (not shown) penetrating through the body of the upper die unit 32 along Z-axis for the vertical probes 40 to be inserted therein. The middle die unit 34 has an accommodating space 341 located in the central region 31 of the probe seat 30 for the vertical probes 40 to be inserted in the accommodating space 341.

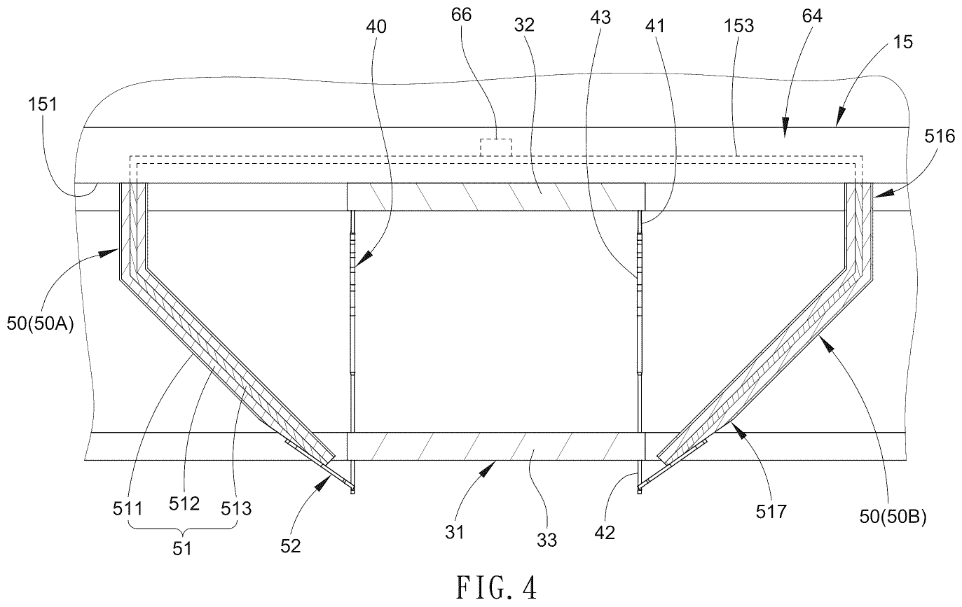

Specifically speaking, as shown in FIG. 4 and FIG. 7, the vertical probe 40 includes an upper end portion 41, a lower end portion 42, and a main body 43 extending into an elongated shape between the upper end portion 41 and the lower end portion 42. The upper end portion 41 of the vertical probe 40 is slidably inserted in the guiding hole of the upper die unit 32. The top end of the upper end portion 41 is adapted to contact the electrically conductive contact of the lower surface 151 of the space transformer 15 so that the vertical probe 40 is electrically connected with the main circuit board 14 through the space transformer 15. The lower end portion 42 of the vertical probe 40 is slidably inserted in the guiding hole 331 of the lower die unit 33. The bottom end of the lower end portion 42 is adapted to contact the electrically conductive contact 22 of the device under test 20. The main body 43 of the vertical probe 40 is accommodated in the accommodating space 341 of the middle die unit 34 and curve-shaped as shown in FIG. 2. When the vertical probe 40 is applied with a force due to the lower end portion 42 thereof contacting the electrically conductive contact 22 of the device under test 20, the main body 43 will further have a slight elastic curving deformation.

For the simplification of the figures and the convenience of illustration, the figures of the present invention only show the vertical probes 40 arranged along the two outer edges 311 and 312 of the central region 31. These vertical probes 40 are only a part of many vertical probes 40 included in the probe head 16. In practice, the other part of the central region 31 is also arranged with vertical probes 40. The vertical probes 40 are arranged in coordination with the form and amount of the electrically conductive contacts 22 of the device under test 20. In the figures of the present invention, the vertical probes are drawn as pre-curved probes, but this is not a direct limit to the type of the vertical probes 40 applicable to the present invention. In fact, the vertical probes 40 applicable to the present invention may at least include straight probes or pre-curved probes. More specifically speaking, the straight probe may be, for example, a forming wire (also referred to as ‘FW’), a microelectromechanical systems (MEMS) wire (also referred to as ‘MW’) or a pogo pin, and so on. The pre-curved probe may be, for example, a cobra probe or a MEMS body pre-curved forming probe, and so on.

Besides, the vertical probe 40 is provided with a curved shape in the air gap, such as the aforementioned accommodating space 341 of the middle die unit 34, by appropriately configuring the vertical probe 40 itself (e.g. the pre-curved probe), or the assistance of the dies which the vertical probe 40 (e.g. the forming wire or MEMS wire included in the straight probe) is inserted through.

In the case that the probe head 16 is of an offset plate type which is applicable to the forming wire or MEMS wire included in the straight probe, specifically speaking, the guiding holes of the upper and lower die units 32 and 33, which the same vertical probe 40 is inserted through, may be offset in position. That is, the imaginary line connecting the centers of the guiding holes of the upper and lower die units 32 and 33, which the same vertical probe 40 is inserted through, is not parallel to a vertical direction. The vertical direction is parallel to Z-axis as shown in FIG. 2, and perpendicular to a reference plane. The reference plane may be parallel to a transversely extending plane of each die. Accordingly, the vertical probe 40 accommodated in the guiding holes of the upper and lower die units 32 and 33 is deformed with respect to a longitudinal extending axis thereof, which is parallel to Z-axis as shown in FIG. 2. The longitudinal extending axis is configured being perpendicular to the reference plane. The upper and lower die units 32 and 33 may be parallel to each other, and extend along the reference plane. The semiconductor wafer under test, the device under test, and the board of the space transformer 15 may also extend along the reference plane.

In the case that the vertical probe 40 is the pre-curved probe, such as the cobra probe shown in FIG. 2, the vertical probe 40 has a pre-deformed configuration so that the upper end portion 41 and lower end portion 42 thereof have an offset therebetween. Especially in such case, the vertical probe 40 includes a pre-deformed part. The pre-deformed part can assist the vertical probe 40 to appropriately curve, even when the probe head 16 has not contacted the device under test 20 yet. The vertical probe 40 is further deformed during the operation thereof, when it is pressed on and contact the device under test 20. It should be noticed that for the appropriate operation of the probe head 16, the vertical probes 40 may have an appropriate capability in axially moving in the guiding holes. In this way, when a probe malfunctions, it can be removed and replaced by another contact probe, so that it is unnecessary to replace the whole probe head. The axially moving capability, especially when the vertical probes slide in the guiding holes, contrasts with the normal safety requirements of the probe head during its operation.

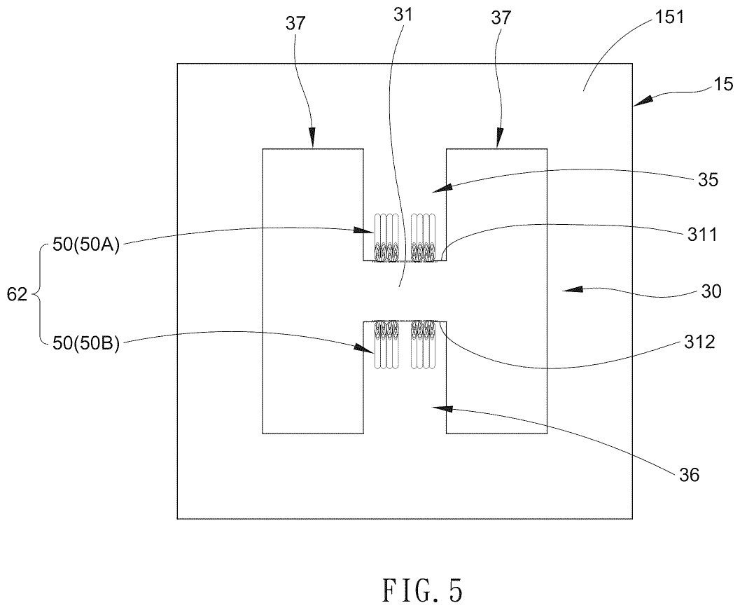

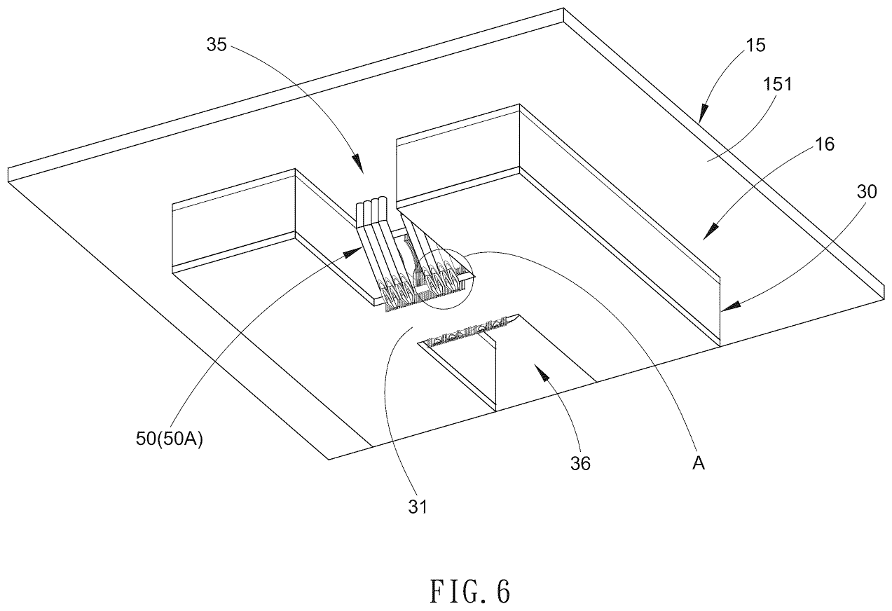

As shown in FIG. 5 and FIG. 6, the probe seat 30 includes two openings 35 and 36 located on two opposite sides of the central region 31, i.e. the outer edges 311 and 312, respectively. Each of the openings 35 and 36 penetrates through the upper, middle and lower die units 32, 34 and 33. The coaxial probes 50 are accommodated in the openings 35 and 36. The coaxial probe 50 in the present invention is similar to that disclosed in Taiwan Patent No. 1634335B, which the applicant of the present invention applied for before. The appearance of the coaxial probe is like a copper pipe. Actually, the coaxial probe is a semi-rigid coaxial cable, which usually includes an inner conductor, a dielectric material and an outer conductor, and may include an outer material layer as needed. The probe seat 30 is unlimited to be H-shaped. For example, the probe seat 30 may have an elongated shape. However, the H-shaped probe seat 30 is not only adapted for the vertical probes 40 to be disposed in the central region 31, but also adapted for accommodating the coaxial probes 50 in the openings 35 and 36 so that the coaxial probes 50 are located on the two opposite sides of the central region 31 and adjacent to the central region 31. Besides, the H-shaped probe seat 30 has two elongated outside regions 37 parallel to each other, resulting in high structural strength of the probe seat 30 and great connection of the probe seat 30 with the space transformer 15. In this embodiment, the probe seat 30 is H-shaped so that the two openings 35 and 36 are respectively located on the two opposite sides of the central region 31, i.e. the outer edges 311 and 312, and opened on the transverse direction, lateral direction or horizontal direction (X-axis or Y-axis). For example, the openings 35 and 36 in this embodiment are opened toward the positive direction and the negative direction of X-axis respectively. However, in some conditions, the openings 35 and 36 may be a closed type, as long as the coaxial probes 50 can pass through the openings 35 and 36. For example, the probe seat 30 may further include two other outside regions (not shown) respectively facing the outer edges 311 and 312 of the central region 31 with the openings 35 and 36 located therebetween, so that the openings 35 and 36 are shaped as closed rectangles.

As shown in FIG. 3 and FIG. 4, each coaxial probe 50 includes a probe main body 51 and a tip unit 52. The probe main body 51 includes an outer conductor 511, a dielectric layer 512 and an inner conductor 513, which are arranged coaxially from the outside to the inside of the probe main body 51 in order. In this embodiment, the probe main body 51 of the coaxial probe 50 includes a vertical section 514 extending along Z-axis, an inclined section 515 extending downwardly and inclinedly relative to the vertical section 514, an upper end portion 516 located at the upper end of the vertical section 514, and a lower end portion 517 located at the lower end of the inclined section 515. The upper end portion 516 is fixed to the lower surface 151 of the space transformer 15 (e.g. by welding). The lower end portion 517 is located in the lower die unit 33 and adjacent to the central region 31 of the probe seat 30. As shown in FIG. 7, the lower end portion 517 of the probe main body 51 is provided with a bevel by cutting, so that the outer conductor 511, the dielectric layer 512 and the inner conductor 513 are all partially exposed on the bevel. The tip unit 52 is fixed to the bevel. The coaxial probes 50 are disposed on the two opposite sides of the central region 31 of the probe seat 30 in a way that the lower end portions 517 of the probe main bodies 51 are close to the central region 31 of the probe seat 30, and the probe main bodies 51 each extends from the lower end portion 517 toward the upper end portion 516 gradually away from the central region 31 of the probe seat 30. The contact force applied to the electrically conductive contacts 22 of the device under test 20 from the tip unit 52 is adjusted by the geometric arrangement of the probe main body 51 of the coaxial probe 50, such as length, tilt angle, and so on. Such arrangement enables the probes of different types in the same probe seat 30, such as the coaxial probes 50 and the vertical probes 40 in this embodiment, to have similar or identical probe pressure. It can be known from the above description that the inclined section 515 of the probe main body 51 of each coaxial probe 50 is inclined relative to the vertical axis (Z-axis), also inclined relative to the horizontal plane (X-Y plane). The vertical probe 40 is straight on an imaginary plane parallel to the vertical axis, such as the X-Z plane shown in FIG. 3. Therefore, on this imaginary plane, there is an included angle θ between the vertical probe 40 and the inclined section 515 of the coaxial probe 50. The included angle θ is smaller than 90 degrees. The probe pressure of such coaxial probe 50 can be adjusted conveniently, which facilitates the matching of the probe pressure of the coaxial probes 50 with the probe pressure of the vertical probes 40.

Each tip unit 52 in this embodiment includes a substrate 521 made of a metal plate by cutting, and a first tip 522 and a second tip 523, which extend from a terminal end of the substrate 521. The substrate 521 includes an outer frame portion 524 and a central portion 525, which are separated from each other. The outer frame portion 524 is electrically connected with the outer conductor 511 of the probe main body 51. The central portion 525 is electrically connected with the inner conductor 513 of the probe main body 51. The first tip 522 and the second tip 523 extend from the outer frame portion 524 and the central portion 525 respectively, so the first tip 522 and the second tip 523 are electrically connected with the outer conductor 511 and the inner conductor 513 respectively. Besides, the outer frame portions 524 of the substrates 521 of the tip units 52 of two adjacent coaxial probes 50 are connected monolithically, and the monolithically connected part thereof is provided with a third tip 526 extending therefrom. Therefore, the third tip 526 is electrically connected with both the outer conductors 511 of the two adjacent coaxial probes 50. In fact, the outer conductors 511 of the four coaxial probes 50 shown in FIG. 7 are electrically connected with each other, and configured to transmit the ground signal. The inner conductors 513 are each configured to transmit a primary testing signal (non-ground signal). In other words, the first tips 522 and the third tips 526 are all configured to transmit the ground signal, and the second tips 523 are configured to transmit the primary testing signals. Such arrangement realizes that there is the ground signal on both sides of every primary testing signal, making the coaxial probes 50 perform well in transmitting high-frequency signals. Therefore, the coaxial probe 50 is also called high-frequency probe. It can be seen in FIG. 7 that the first, second and third tips 522, 523 and 526 of the coaxial probes 50 are arranged along the outer edge of the central region 31 of the probe seat 30, and substantially arranged with the lower end portions 42 of a part of the vertical probes 40 in a straight line, so they can be used to contact the electrically conductive contacts 22 of the device under test 20 substantially arranged in a straight line. However, the present invention is unlimited to this arrangement.

It can be known from the above description that the probe main body 51 of the coaxial probe 50 in this embodiment has components actually arranged coaxially, which are the outer conductor 511, the dielectric layer 512 and the inner conductor 513. However, the coaxial probe mentioned in the present invention is unlimited to such probe type having the inner and outer conductors, but includes other probe types capable of using the ground signal to protect the testing signal. That can be achieved as long as the coaxial probe 50 has a testing signal transmitting path and a ground signal transmitting path, which are located close to each other. The preferred configuration is the tips are arranged in a GSG or GSGSG manner, wherein G refers to ground signal and S refers to testing signal. The tip units 52 of the two adjacent coaxial probes 50 shown in FIG. 7 have five tips in total. These five tips are arranged in the GSGSG manner. For example, the probe main body of the coaxial probe in the present invention may be a circuit board (flexible circuit board or normal circuit board). The circuit board has a plurality of electrical conductors electrically insulated from each other, i.e. the traces distributed on the circuit board. The electrical conductors can be provided in the aforementioned GSG or GSGSG manner, and electrically connected with the first tip 522 and the second tip 523 (or the third tip 526 as well) of the tip unit 52, so as to form the coaxial probe configuration capable of using the ground signal to protect the testing signal

It should be mentioned here that when the vertical probes 40 and the coaxial probes 50 are in use to test the device under test 20, a tip 422 (as shown in FIG. 7) of the lower end portion 42 of each vertical probe 40 and the first, second and third tips 522, 523 and 526 of the coaxial probes 50 are in contact with the electrically conductive contacts 22 of the device under test 20, and then relatively displace for a distance called overdrive (also referred to as ‘OD’) or called overtravel (also referred to as ‘OT’) to further approach each other. That makes the main bodies 43 of the vertical probes 40 compressed and deformed in a buckling manner, and makes the tips 422 of the vertical probes 40 and the first, second and third tips 522, 523 and 526 of the coaxial probes 50 pressed and contact the electrically conductive contacts 22 of the device under test 20. During this process, the force applied to the electrically conductive contact 22 of the device under test 20 from each aforementioned tip is defined as a contact force in the present invention. The larger the contact force, the smaller the contact resistance between the tip and the electrically conductive contact 22 of the device under test 20. The contact force is measured by applying the OD/OT to the probes, and meanwhile measuring the value of the force applied by each tip on a force sensor.

Further speaking, the aforementioned contact force includes a probe deformation force and a probe friction. The probe deformation force refers to the force required for the elastic deformation of the probe in the process of the aforementioned overdrive. The probe deformation force depends on many factors, such as the material properties of the probe (e.g. Young's modulus, elastic modulus), the final geometric shape and size of the probe (e.g. length, thickness, width, and so on). The probe friction refers to the friction applied to the probe from the dies, such as the friction applied to the vertical probe 40 from the inner wall of the aforementioned guiding hole of the upper die unit 32 and/or the inner wall of the aforementioned guiding hole 331 of the lower die unit 33. The aforementioned contact force can steadily push the upper end portion 41 of the vertical probe 40 to press the contact pad of the aforementioned space transformer 15, and then buckle the main body 43 of the vertical probe 40. That can make the vertical probe 40 and the electrically conductive contact 22 of the device under test 20 electrically connected with each other, thereby making the electrically conductive contact 22 of the device under test 20 electrically connected to the tester 12 through the vertical probe 40. For example, when the first tip 522 and second tip 523 (or third tip 526 as well) of each coaxial probe 50 are in contact with the device under test 20 and applied with an appropriate OD/OT (e.g. 2 mils), in the case that the tip width is 20-30 μm, the contact force is about 4.5-10 gw. That means the force applied to each electrically conductive contact 22 of the device under test 20 from the coaxial probe 50 is about 4.5-10 gram-weights (gw). When the tip 422 of the lower end portion 42 of each vertical probe 40 is in contact with the device under test 20 and applied with an appropriate OD/OT, according to the vertical probe type (pre-curved probe or straight probe), the contact force thereof is about 1.5-4 gw. That means the force applied to each electrically conductive contact 22 of the device under test 20 from the vertical probe 40 is about 1.5-4 gram-weights (gw).

The above-described adjustment of the contact force applied to the electrically conductive contacts 22 of the device under test 20 from the tip unit 52 can make the first tip 522 and second tip 523 (or third tip 526 as well) of each coaxial probe 50 match the tip 422 of the lower end portion 42 of each vertical probe 40 in contact force, which means the contact forces of the tips are similar or identical. More specifically speaking, among the contact force of anyone of the first tip 522 and the second tip 523 of the coaxial probe 50 and the contact force of the tip 422 of the vertical probe 40, the larger one is smaller than the double of the smaller one. Therefore, the ratio of the contact force of anyone of the first tip 522 and the second tip 523 of the coaxial probe 50 to the contact force of the tip 422 of the vertical probe 40 is larger than 0.5 and smaller than 2. As a result, when the device under test 20 is tested by the coaxial probes 50 and the vertical probes 40, the first tips 522 and second tips 523 (or third tips 526 as well) of the coaxial probes 50 and the tips 422 of the vertical probes 40 generate similar or identical probe pressure to the electrically conductive contacts 22 of the device under test 20.

Besides, the first tip 522 and second tip 523 (or third tip 526 as well) of each coaxial probe 50 can match the tip 422 of the lower end portion 42 of each vertical probe in wear rate, which means the wear rates of the tips are similar or identical. For example, the tip width or diameter of the first tip 522 and second tip 523 (or third tip 526 as well) of each coaxial probe 50 is about 20-30 μm, the tip diameter of the pre-curved probe is about 45-63.5 μm, and the tip size of the straight probe is about 42-66 μm. To make the wear rates similar or identical, in the practical test, the tips of the probes should be applied with similar contact force per unit area, wherein the contact force per unit area equals to the contact force or probe pressure (F) the tip bears divided by the cross-sectional area (A) of the tip, i.e. F/A. That is because the wear rate is positively correlated with F/A. This feature can be attained by providing the first tips 522 and the second tips 523 of the coaxial probes 50 and the tips 422 of the vertical probes 40 similar or identical outer diameters to make the cross-sectional areas of the aforementioned tips equivalent, thereby making them identical or similar in F/A value. More specifically speaking, among the outer diameter of anyone of the first tip 522 and the second tip 523 of the coaxial probe 50 and the outer diameter of the tip 422 of the vertical probe 40, the larger one is smaller than the double of the smaller one. Therefore, the ratio of the outer diameter of anyone of the first tip 522 and the second tip 523 of the coaxial probe 50 to the outer diameter of the tip 422 of the vertical probe 40 is larger than 0.5 and smaller than 2. As a result, the first tips 522 and second tips 523 (or third tips 526 as well) of the coaxial probes 50 and the tips 422 of the vertical probes 40 will have similar or identical wear rates, thereby maintaining great probe planarity even after prolonged use, which means the terminal ends of the tips are approximately located on a same horizontal plane. Because different probe types are different in tip shape, the outer diameter mentioned in the present invention refers to the tip width or diameter for the coaxial probe, refers to the tip diameter for the pre-curved probe, and refers to the tip size (tip width or diameter) for the straight probe.

As shown in FIG. 3 to FIG. 5, the coaxial probes 50 in this embodiment are disposed on two opposite sides of the central region 31, and accommodated in the openings 35 and 36 located on the two opposite sides. Further speaking, the coaxial probes 50 in the opening 35 are also called first loopback probes 50A, and the coaxial probes 50 in the opening 36 are also called second loopback probes 50B. The first loopback probes 50A are paired with the second loopback probes 50B respectively to compose loopback probe pairs 62. More specifically speaking, there are eight loopback probe pairs 62 shown in FIG. 5. Each of the loopback probe pairs 62 is composed of a first loopback probe 50A and a second loopback probe 50B. In the present invention, the loopback probe pair 62 is adapted to be configured as a part of a loopback test path. That is, the first and second loopback probes 50A and 50B of each loopback probe pair 62 are connected by a connecting structure, so that the first and second loopback probes 50A and 50B and the connecting structure are collectively configured as a loopback test path. In this embodiment, the connecting structure is a loopback test circuit 153 of the space transformer 15, as shown in FIG. 4. The upper end portion 516 of the probe main body 51 of the first loopback probe 50A is connected to an end of the loopback test circuit 153. The upper end portion 516 of the probe main body 51 of the second loopback probe 50B is connected to the other end of the loopback test circuit 153. The first and second loopback probes 50A and 50B and the loopback test circuit 153 are electrically connected with each other to form a loopback test path 64.

As a result, each loopback probe pair 62 is adapted to transmit a loopback signal. For example, the device under test 20 generates the loopback signal to the first loopback probe 50A. The loopback signal is transmitted through the first loopback probe 50A, the loopback test circuit 153 and the second loopback probe 50B in order, and then transmitted back to the device under test 20 from the second loopback probe 50B. Alternatively, the transmitting direction may be reverse. Therefore, the probe card 13 of the present invention can perform a loopback test to the device under test 20, and the probes performing the loopback test are the coaxial probes 50. The coaxial probes 50 transmit the aforementioned loopback signal by the inner conductors 513, and transmit the ground signal by the outer conductors 511, that is beneficial for high-frequency signal transmission, so that the probe card 13 of the present invention can meet the high-frequency loopback test requirements, thereby applicable to test electronic devices for high-speed network applications.

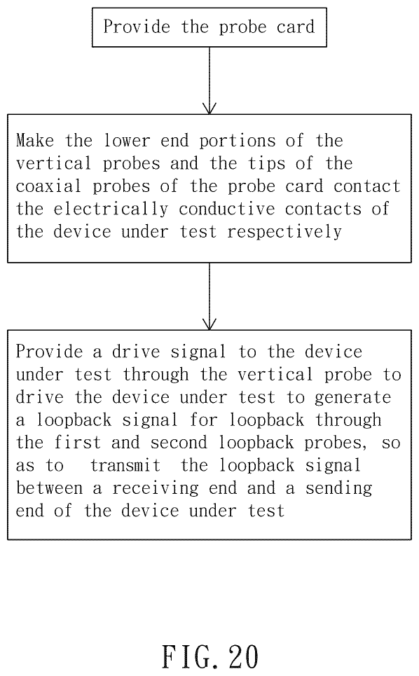

Further speaking, the testing method provided by the present invention includes the following steps a) to c), as shown in FIG. 20.
a) Provide the above-described probe card 13.
b) Make the lower end portions 42 of the vertical probes 40 and the first tips 522 and second tips 523 (or third tips 526 as well) of the coaxial probes 50 of the probe card 13 contact the electrically conductive contacts 22 of the device under test 20 respectively.
c) Provide a drive signal to the device under test 20 through the vertical probe of the probe card 13 to drive the device under test 20 to generate a loopback signal of a given type, and make loopback of the loopback signal progress through the first loopback probe 50A and the second loopback probe 50B, so that the loopback signal is transmitted by the first loopback probe 50A and the second loopback probe 50B between a receiving end and a sending end of the device under test 20.

For further ensuring the integrity and accuracy of the signal, two adjacent loopback probe pairs 62 can be configured to transmit a differential signal. That is, two adjacent loopback test paths 64 are arranged as a differential pair for the differential signal to be transmitted through the two loopback test paths 64. In other words, the loopback signal of the given type mentioned in the above-described testing method can be the differential signal. As a result, the signal transmission is less susceptible to noise interference, thereby ensuring the integrity and accuracy of the signal. However, the loopback signal transmitted by the present invention is unlimited to the differential signal. Each loopback probe pair 62 can be configured to transmit a single-ended signal. In other words, the loopback signal of the given type mentioned in the above-described testing method can be the single-ended signal.

As shown in FIG. 4, the probe card of the present invention may be provided with an electronic component 66 disposed on the loopback test path 64 as needed, so as to use the electronic component 66 to adjust the required properties of the loopback test path 64 and the signal it transmits. For example, the electronic component 66 may be an electronic component having signal filtering ability for filtering out DC signals while allowing only AC signals to pass through the loopback test path 64 (DC Blocking/AC Coupling), such as a filter capacitor. Specifically, it may be, for example, a silicon capacitor. In the arrangement in this embodiment, the loopback test circuit 153 of the space transformer 15 is convenient to be provided with the electronic component 66 in a way that the electronic component 66 is electrically connected with the inner conductors 513 of the first and second loopback probes 50A and 50B through the loopback test circuit 153 so as to exert its effect on the signal transmitted by the first and second loopback probes 50A and 50B.

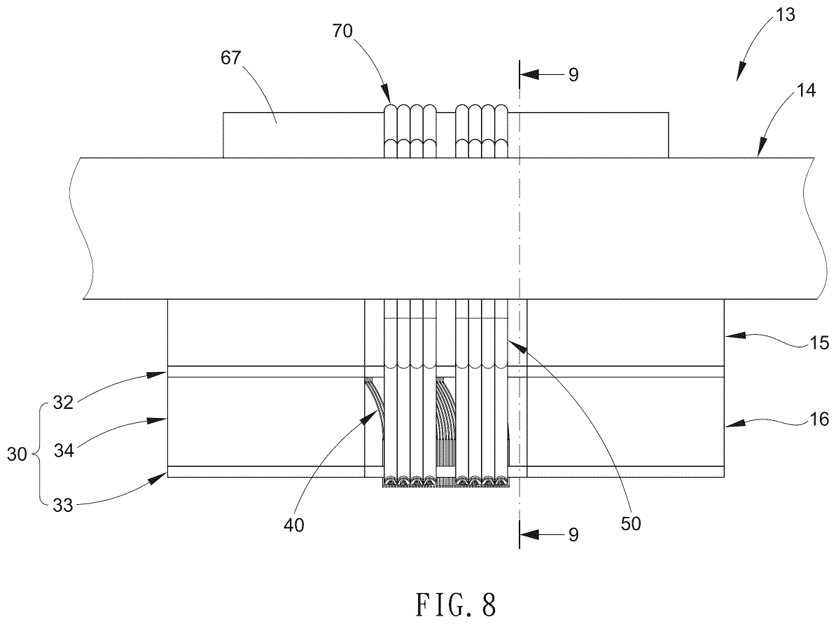

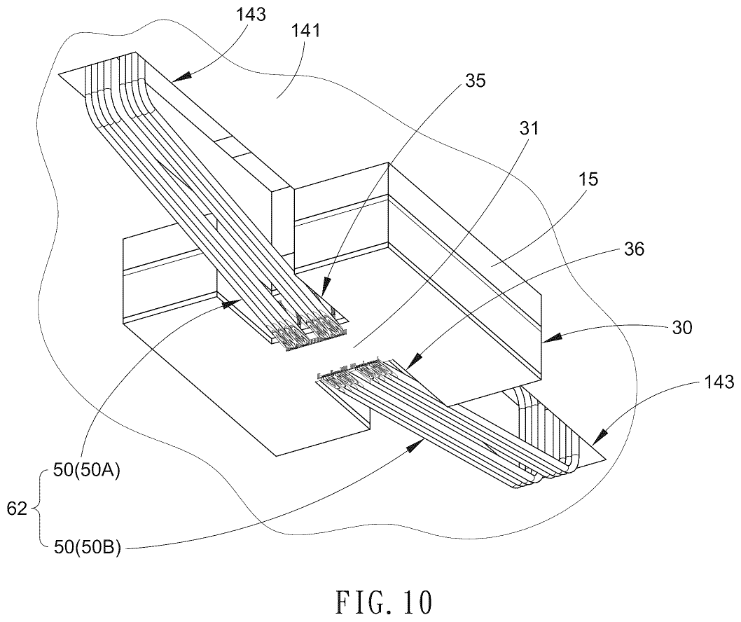

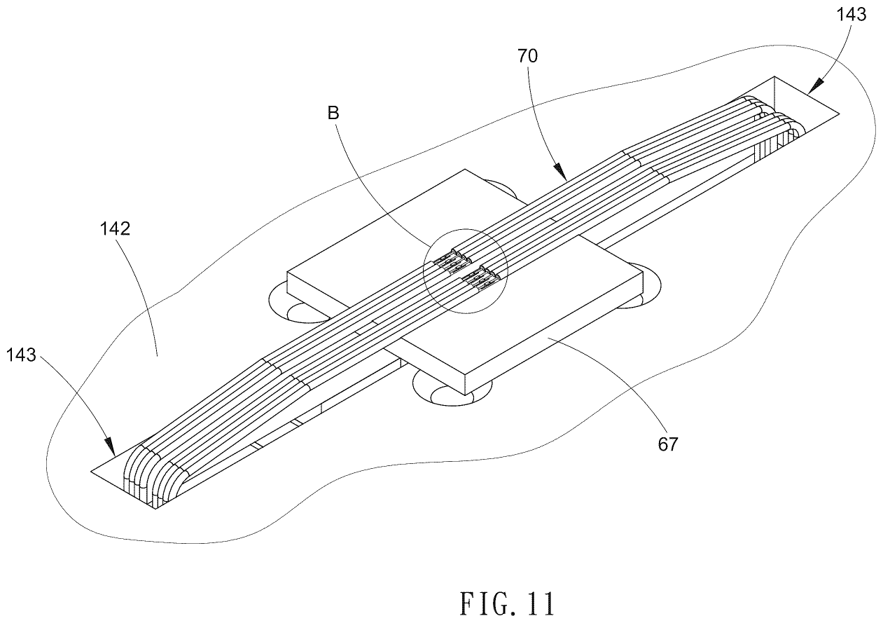

Referring to FIG. 8 to FIG. 12, the probe card 13 according to a second preferred embodiment of the present invention is similar to that in the first preferred embodiment, but the primary difference therebetween lies in that the first and second loopback probes 50A and 50B of each loopback probe pair 62 in this embodiment are not electrically connected by the space transformer 15, but by a coaxial structure 70.

Specifically speaking, in this embodiment, not only the probe seat 30 is H-shaped, but the space transformer 15 also has the same H-shape. The main circuit board 14 has two grooves 143 penetrating through the upper surface 142 and the lower surface 141. The probe main bodies 51 of the first and second loopback probes 50A and 50B penetrate through the probe seat 30, the space transformer 15 and the grooves 143 of the main circuit board 14. The coaxial structure 70 is located on the upper surface 142 of the main circuit board 14, and connects the probe main bodies 51 of the first and second loopback probes 50A and 50B.

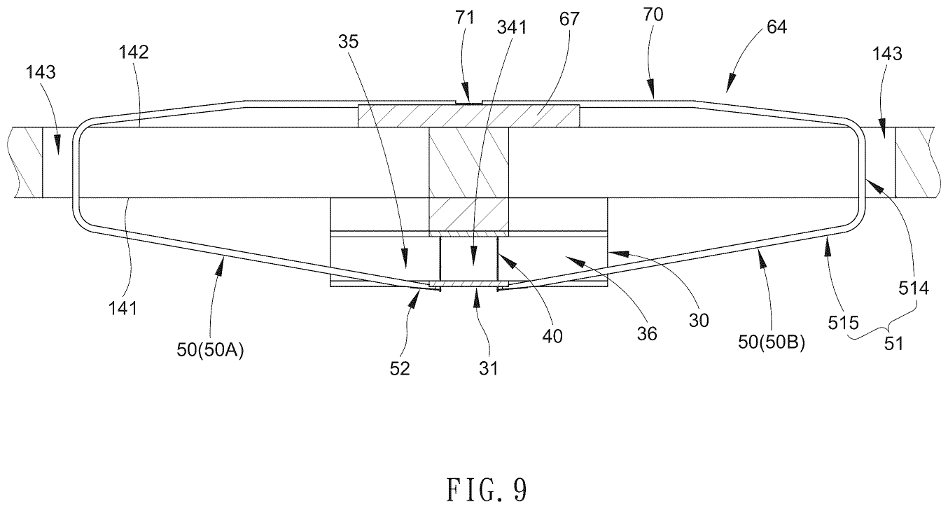

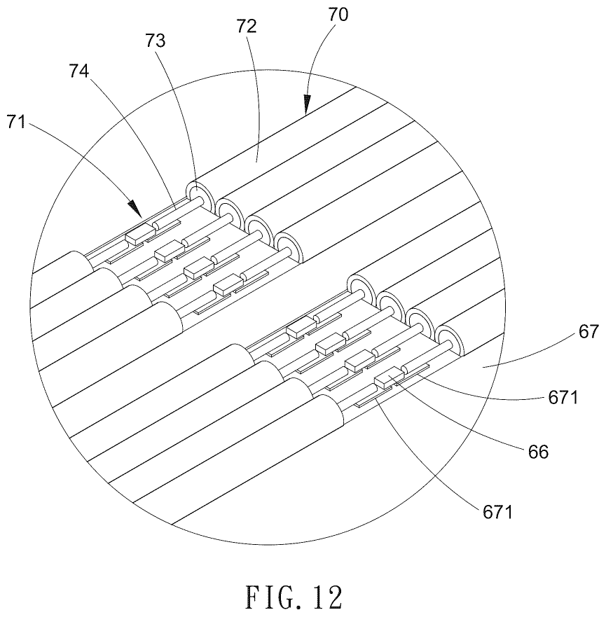

It can be seen in FIG. 9 that in this embodiment, the coaxial structure 70 and the probe main bodies 51 of the first and second loopback probes 50A and 50B are a same element, but the middle section of the coaxial structure 70 has a breach 71, that will be specified hereinafter. Therefore, the inner configuration of the coaxial structure 70 is the same with that of the probe main body 51, including an outer conductor 72, a dielectric layer 73 and an inner conductor 74, which are arranged coaxially from the outside to the inside of the coaxial structure 70 in order, as shown in FIG. 12. The outer conductors 511 of the first and second loopback probes 50A and 50B and the outer conductor 72 of the coaxial structure 70 are connected monolithically, thereby electrically connected with each other. The inner conductors 513 of the first and second loopback probes 50A and 50B and the inner conductor 74 of the coaxial structure 70 are connected monolithically, thereby electrically connected with each other. As a result, the first and second loopback probes 50A and 50B of the loopback probe pair 62 and the coaxial structure 70 collectively form a loopback test path 64.

The aforementioned breach 71 of the coaxial structure 70 is adapted for an electronic component 66 as shown in FIG. 12 to be disposed on the loopback test path 64. The electronic component 66 in this embodiment is disposed on a connecting board 67. The connecting board 67 is disposed on the upper surface 142 of the main circuit board 14. The coaxial structure 70 is partially disposed on the connecting board 67, and the connecting board 67 is provided thereon with a plurality of pairs of connecting conductors 671. Each electronic component 66 is electrically connected with a pair of connecting conductors 671, and located in the breach 71 of the coaxial structure 70. The inner conductor 74 of the coaxial structure 70 is electrically connected with the electronic component 66 through the connecting conductors 671. However, the electronic component 66 is unlimited to be disposed in this manner. For example, the electronic component 66 can be directly electrically connected with the inner conductor 74 of the coaxial structure 70. The position where the electronic component 66 is disposed on the coaxial structure 70 is unlimited, which is unnecessary to be the central position of the coaxial structure 70 on the longitudinal direction thereof.

In this embodiment, the loopback test path 64 is formed in a way that the first and second loopback probes 50A and 50B penetrate through the probe seat 30, the space transformer 15 and the main circuit board 14, and the first and second loopback probes 50A and 50B are connected by the coaxial structure 70 on the upper surface 142 of the main circuit board 14. Therefore, the probe card in this embodiment can also achieve the same effects with the first preferred embodiment. It can meet the high-frequency loopback test requirements.

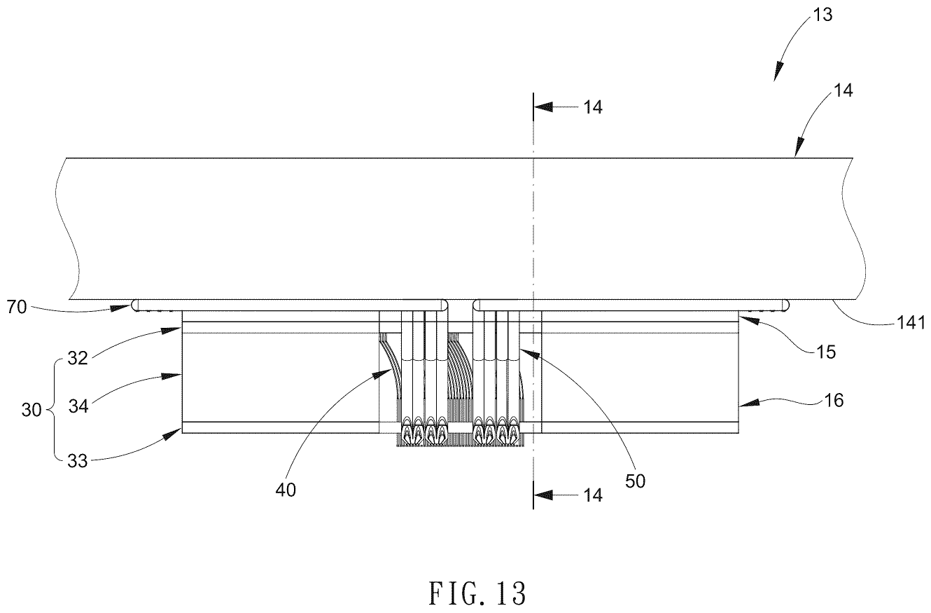

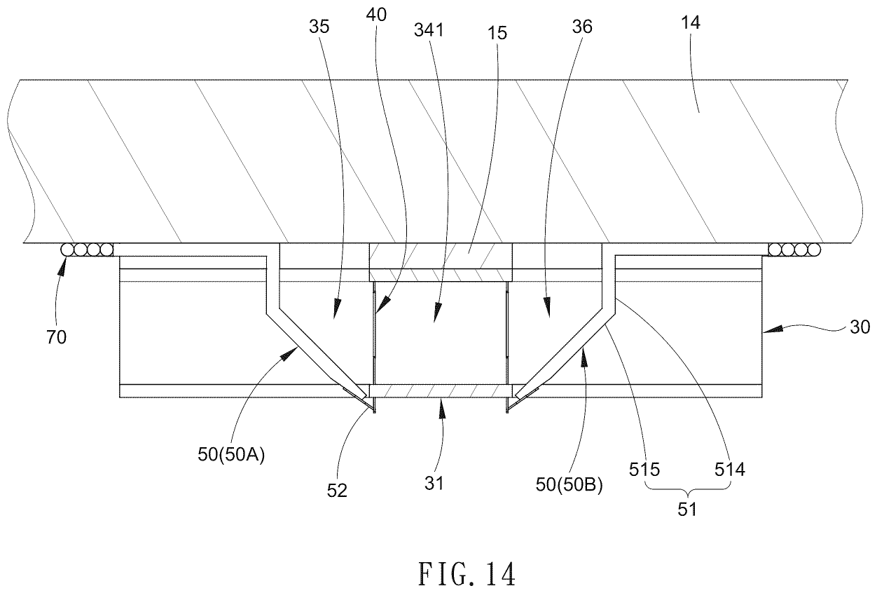

Referring to FIG. 13 to FIG. 16, the probe card 13 according to a third preferred embodiment of the present invention is similar to that in the second preferred embodiment, but the primary difference therebetween lies in that the probe main bodies 51 of the first and second loopback probes 50A and 50B in this embodiment penetrate through only the probe seat 30 and the space transformer 15, but not penetrating through the main circuit board 14. The coaxial structure 70 connecting the first and second loopback probes 50A and 50B is located on the lower surface 141 of the main circuit board 14, and disposed along a periphery 154 of the space transformer 15.

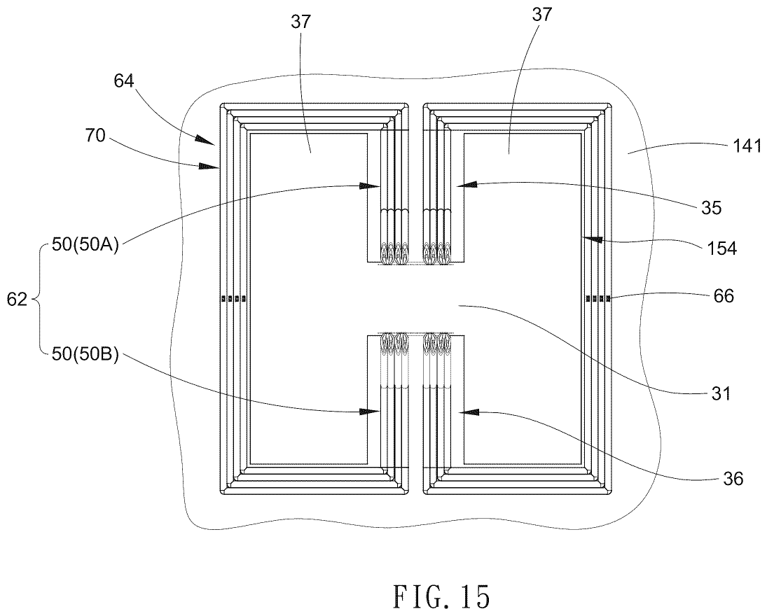

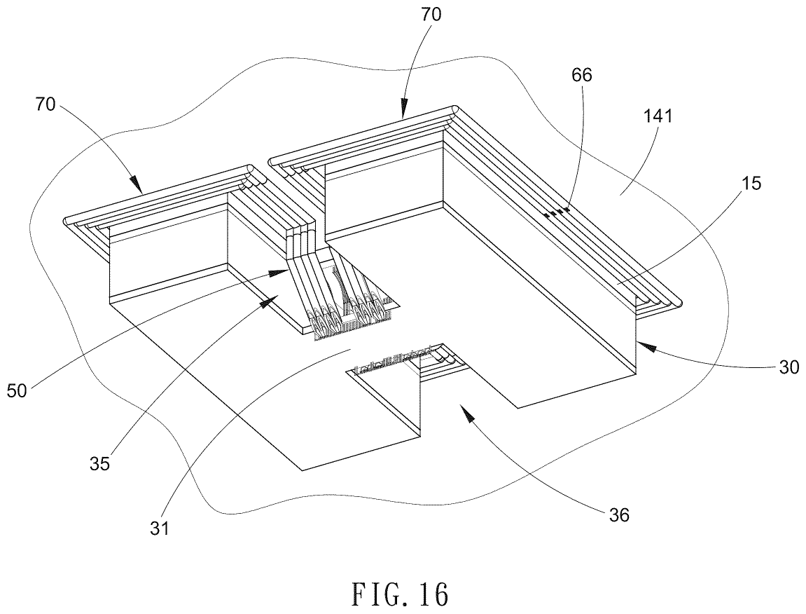

In this embodiment, the loopback test path 64 is formed in a way that the first and second loopback probes 50A and 50B penetrate through the probe seat 30 and the space transformer 15, and the first and second loopback probes 50A and 50B are connected by the coaxial structure 70 on the lower surface 141 of the main circuit board 14. Therefore, the probe card in this embodiment can also achieve the same effects with the first preferred embodiment. It can meet the high-frequency loopback test requirements. The coaxial structure 70 in this embodiment is disposed along the periphery 154 of the space transformer 15, thereby prevented from the interference with the vertical probes 40 and/or the circuits of the space transformer 15. That makes it relatively easier to arrange the coaxial structure 70. Besides, it is convenient to dispose the electronic component 66 on the coaxial structure 70 located on the periphery 154 of the space transformer 15. For example, the electronic component 66 can be disposed on the surface of the coaxial structure 70 facing downward, as shown in FIG. 15 and FIG. 16.

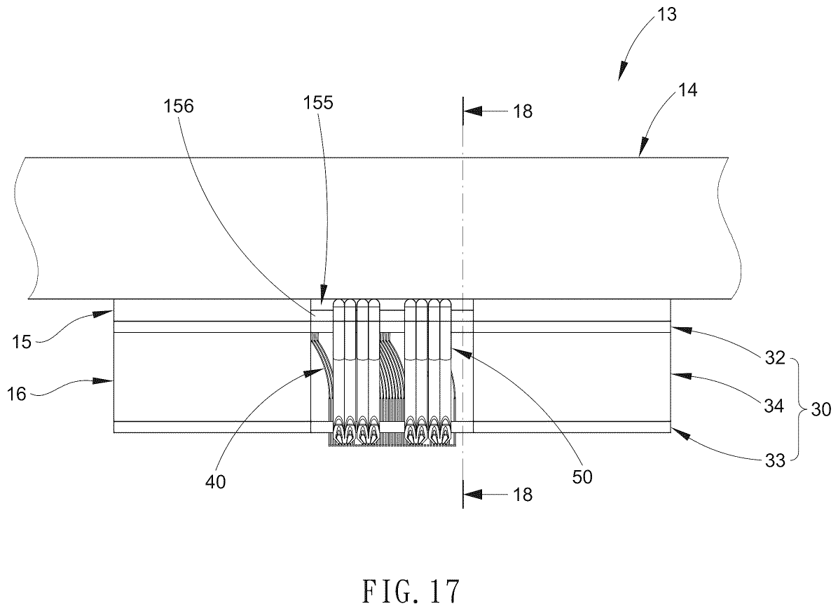

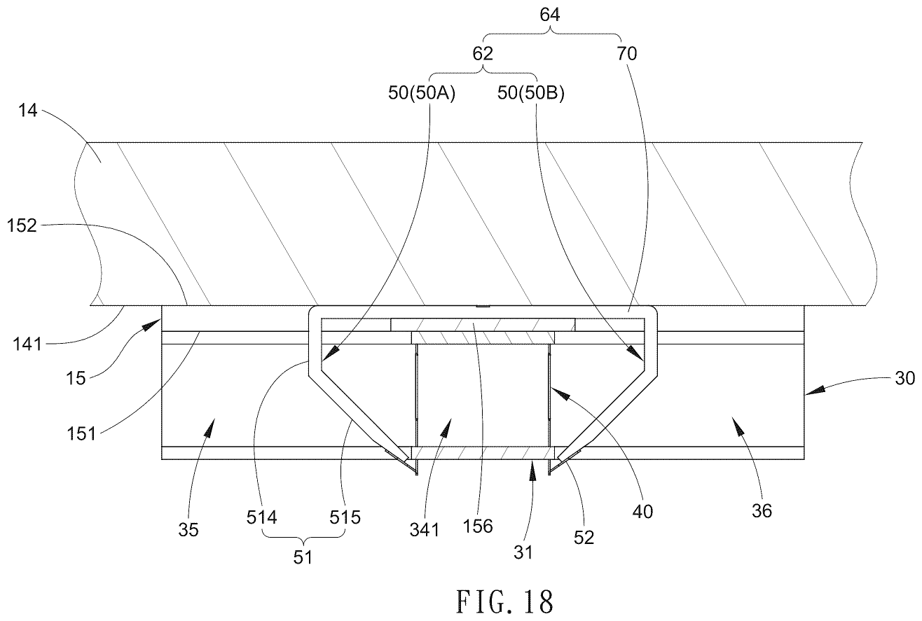

Referring to FIG. 17 to FIG. 19, the probe card 13 according to a fourth preferred embodiment of the present invention is similar to that in the third preferred embodiment, but the primary difference therebetween lies in that the coaxial structure 70 connecting the first and second loopback probes 50A and 50B is located above the central region 31 of the probe seat 30 and penetrates through the space transformer 15.

Specifically speaking, the space transformer 15 in this embodiment includes an accommodating recess 155 recessed from the upper surface 152. The accommodating recess 155 is located above the central region 31 of the probe seat 30. The circuits inside the space transformer 15 are primarily arranged in a circuit layer 156 located between the lower surface 151 and the accommodating recess 155. The coaxial structure 70 connecting the first and second loopback probes 50A and 50B is inserted in the accommodating recess 155. That is, the coaxial structure 70 is located between the lower surface 141 of the main circuit board 14 and the circuit layer 156 of the space transformer 15.

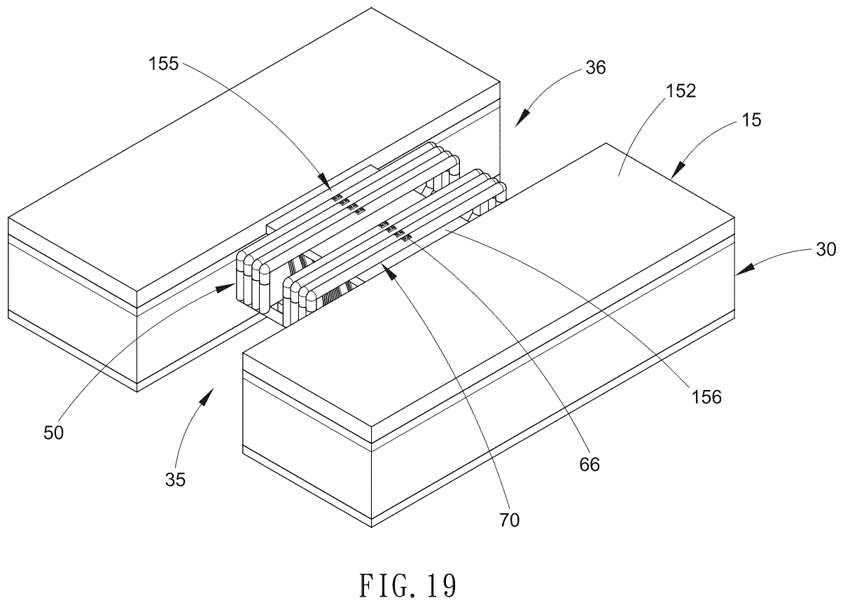

In this embodiment, the loopback test path 64 is formed in a way that the first and second loopback probes 50A and 50B penetrate through the probe seat 30 and the space transformer 15, and the first and second loopback probes 50A and 50B are connected by the coaxial structure 70 on the lower surface 141 of the main circuit board 14. Therefore, the probe card in this embodiment can also achieve the same effects with the first preferred embodiment. It can meet the high-frequency loopback test requirements. The coaxial structure 70 in this embodiment extends through the accommodating recess 155 of the space transformer 15. Such connection has a relatively shorter path, so it can save material and can reduce signal interference. The coaxial structure 70 in this embodiment can be also provided with the electronic component 66. For example, the electronic component 66 can be disposed on the surface of the coaxial structure 70 facing upward, as shown in FIG. 19.

The invention being thus described, it will be obvious that the same may be varied in many ways. Such variations are not to be regarded as a departure from the scope of the invention, and all such modifications as would be obvious to one skilled in the art are intended to be included within the scope of the following claims.

What is claimed is:

1. A probe head of a probe card for a loopback test, which is adapted to test a device under test having a plurality of electrically conductive contacts, the probe head comprising:
a probe seat comprising at least one die unit, the die unit comprising a plurality of guiding holes;
a plurality of vertical probes, each of the vertical probes comprising an upper end portion, a lower end portion, and a main body extending into an elongated shape between the upper end portion and the lower end portion, the vertical probes being slidably inserted in the guiding holes, the lower end portions of the vertical probes being adapted to contact the electrically conductive contacts of the device under test; and
a plurality of coaxial probes disposed in the probe seat, each of the coaxial probes comprising a probe main body and a tip unit, the probe main body comprising a plurality of electrical conductors electrically insulated from each other, the tip unit being disposed at a lower end portion of the probe main body, the tip unit comprising a first tip and a second tip, the first tip and the second tip being electrically connected with two of the electrical conductors of the probe main body respectively, the first tip and the second tip being adapted to contact the electrically conductive contacts of the device under test;
wherein the plurality of coaxial probes comprise a first loopback probe and a second loopback probe; the first loopback probe and the second loopback probe compose a loopback probe pair; the loopback probe pair is adapted to be configured as a part of a loopback test path.

2. The probe head as claimed in claim 1, wherein the probe main bodies of the plurality of coaxial probes are located outside the plurality of vertical probes.

3. The probe head as claimed in claim 1, wherein the guiding holes of the die unit each extend along a vertical axis; the probe main body of each of the coaxial probes comprises an inclined section inclined relative to the vertical axis; on an imaginary plane parallel to the vertical axis, the vertical probe is straight, and there is an included angle between the vertical probe and the inclined section of the coaxial probe.

4. The probe head as claimed in claim 3, wherein the included angle between the vertical probe and the inclined section of the coaxial probe on the imaginary plane is smaller than 90 degrees.

5. The probe head as claimed in claim 1, wherein the plurality of coaxial probes comprise two said first loopback probes and two said second loopback probes; the two first loopback probes and the two second loopback probes compose two said loopback probe pairs; the two loopback probe pairs are adapted to be configured as parts of two said loopback test paths; the two loopback probe pairs are arranged to transmit a differential signal.

6. The probe head as claimed in claim 1, wherein the loopback probe pair is arranged to transmit a single-ended signal.

7. The probe head as claimed in claim 1, wherein the at least one die unit comprises an upper die unit and a lower die unit; the probe seat comprises an opening penetrating through the upper die unit and the lower die unit; the coaxial probes are accommodated in the opening.

8. The probe head as claimed in claim 7, wherein the probe seat is H-shaped and comprises a central region, and two said openings located on two opposite sides of the central region respectively; the coaxial probes are accommodated in the two openings.

9. The probe head as claimed in claim 1, wherein the probe seat comprises a central region; the coaxial probes are arranged on two opposite sides of the central region.

10. The probe head as claimed in claim 9, wherein the vertical probes are arranged in the central region; the first tips and second tips of the coaxial probes are arranged on said two opposite sides of the central region.

11. The probe head as claimed in claim 1, wherein the lower end portions of at least a part of the vertical probes and the first tips and second tips of at least a part of the coaxial probes are substantially arranged in a straight line.

12. The probe head as claimed in claim 1, wherein the first loopback probe and the second loopback probe are electrically connected with a loopback test circuit of a space transformer.

13. The probe head as claimed in claim 12, wherein an upper end portion of the probe main body of the first loopback probe and an upper end portion of the probe main body of the second loopback probe are connected with the space transformer and thereby electrically connected with the loopback test circuit.

14. The probe head as claimed in claim 12, wherein the loopback test path is provided thereon with an electronic component having signal filtering ability; the electronic component is located on the loopback test circuit of the space transformer.

15. The probe head as claimed in claim 1, wherein the plurality of electrical conductors of the probe main body of each of the coaxial probes comprise an outer conductor and an inner conductor; the probe main body further comprises a dielectric layer; the outer conductor, the dielectric layer and the inner conductor are arranged coaxially from an outside to an inside of the probe main body in order; the first tip and the second tip of the tip unit are electrically connected with the outer conductor and the inner conductor respectively.

16. The probe head as claimed in claim 15, wherein the first loopback probe and the second loopback probe are connected by a coaxial structure; the coaxial structure comprises an outer conductor, a dielectric layer and an inner conductor, which are arranged coaxially from an outside to an inside of the coaxial structure in order; the outer conductor of the first loopback probe and the outer conductor of the second loopback probe are electrically connected with the outer conductor of the coaxial structure; the inner conductor of the first loopback probe and the inner conductor of the second loopback probe are electrically connected with the inner conductor of the coaxial structure.

17. The probe head as claimed in claim 16, wherein the loopback test path is provided thereon with an electronic component having signal filtering ability; the electronic component is located in the coaxial structure and electrically connected with the inner conductor of the coaxial structure.

18. The probe head as claimed in claim 1, wherein the vertical probes are adapted to transmit signals between the device under test and a tester; the coaxial probes only transmit signals to each other and transmit signals to and from the device under test.

19. The probe head as claimed in claim 1, wherein a ratio of a contact force of anyone of the first tip and the second tip to a contact force of a tip of the vertical probe is larger than 0.5 and smaller than 2.

20. The probe head as claimed in claim 1, wherein a ratio of an outer diameter of anyone of the first tip and the second tip to an outer diameter of a tip of the vertical probe is larger than 0.5 and smaller than 2.

21. A probe card for a loopback test, which is adapted to be applied in a probe system for testing a device under test, the probe card comprising:
a probe head as claimed in claim 1;
a main circuit board for being electrically connected to a tester, the main circuit board comprising an upper surface and a lower surface opposite to the upper surface; and
a space transformer disposed between the probe head and the lower surface of the main circuit board so that the vertical probes of the probe head are electrically connected with the main circuit board through the space transformer.

22. The probe card as claimed in claim 21, wherein the probe main bodies of the first loopback probe and the second loopback probe of the probe head penetrate through the probe seat, the space transformer and the main circuit board.

23. The probe card as claimed in claim 22, wherein the plurality of electrical conductors of the probe main body of each of the coaxial probes comprise an outer conductor and an inner conductor; the probe main body further comprises a dielectric layer; the outer conductor, the dielectric layer and the inner conductor are arranged coaxially from an outside to an inside of the probe main body in order; the first tip and the second tip of the tip unit are electrically connected with the outer conductor and the inner conductor respectively; the first loopback probe and the second loopback probe of the probe head are connected by a coaxial structure; the coaxial structure comprises an outer conductor, a dielectric layer and an inner conductor arranged coaxially from an outside to an inside of the coaxial structure in order; the outer conductor of the first loopback probe and the outer conductor of the second loopback probe are electrically connected with the outer conductor of the coaxial structure; the inner conductor of the first loopback probe and the inner conductor of the second loopback probe are electrically connected with the inner conductor of the coaxial structure; the coaxial structure is located on the upper surface of the main circuit board.

24. The probe card as claimed in claim 21, wherein the probe main bodies of the first loopback probe and the second loopback probe of the probe head penetrate through the probe seat and the space transformer.

25. The probe card as claimed in claim 24, wherein the plurality of electrical conductors of the probe main body of each of the coaxial probes comprise an outer conductor and an inner conductor; the probe main body further comprises a dielectric layer; the outer conductor, the dielectric layer and the inner conductor are arranged coaxially from an outside to an inside of the probe main body in order; the first tip and the second tip of the tip unit are electrically connected with the outer conductor and the inner conductor respectively; the first loopback probe and the second loopback probe of the probe head are connected by a coaxial structure; the coaxial structure comprises an outer conductor, a dielectric layer and an inner conductor arranged coaxially from an outside to an inside of the coaxial structure in order; the outer conductor of the first loopback probe and the outer conductor of the second loopback probe are electrically connected with the outer conductor of the coaxial structure; the inner conductor of the first loopback probe and the inner conductor of the second loopback probe are electrically connected with the inner conductor of the coaxial structure; the coaxial structure is located on the lower surface of the main circuit board.

26. The probe card as claimed in claim 25, wherein the coaxial structure is disposed along a periphery of the space transformer.

27. The probe card as claimed in claim 25, wherein the space transformer comprises an upper surface facing toward the main circuit board, a lower surface facing toward the probe head, an accommodating recess recessed from the upper surface of the space transformer, and a circuit layer located between the accommodating recess and the lower surface of the space transformer; the coaxial structure is inserted in the accommodating recess and located between the lower surface of the main circuit board and the circuit layer.

28. A probe system for testing a device under test, the probe system comprising:
a chuck for supporting the device under test;
a tester; and
a probe card as claimed in claim 21, which is electrically connected with the tester for contacting the device under test to make the tester electrically connected with the device under test for performing an electrical property testing process.

29. A testing method for testing a device under test having a plurality of electrically conductive contacts, the testing method comprising the steps of:
providing a probe card having the probe head as claimed in claim 1;
making the lower end portions of the vertical probes and the first tips and second tips of the coaxial probes of the probe card contact the electrically conductive contacts of the device under test respectively; and
providing a drive signal to the device under test through the vertical probe of the probe card to drive the device under test to generate a loopback signal of a given type, and making loopback of the loopback signal progress through the first loopback probe and the second loopback probe, so that the first loopback probe and the second loopback probe transmit the loopback signal between a receiving end and a sending end of the device under test.

30. The testing method as claimed in claim 29, wherein the probe head comprises two said loopback probe pairs; the loopback signal of said given type is a differential signal.

31. The testing method as claimed in claim 29, wherein the loopback signal of said given type is a single-ended signal.

32. A tested device, the tested device being a device which has been tested through an electrical property testing process, the electrical property testing process being performed by using the testing method as claimed in claim 29.
